(19) United States
(12) Patent Application Publication
(10) Pub. No.: US 2025/0273270 A1
(43) Pub. Date: Aug. 28, 2025

(54) MEMORY DEVICES, MEMORY SYSTEMS, AND OPERATION METHODS

(71) Applicant: YANGTZE MEMORY TECHNOLOGIES CO., LTD., Wuhan (CN)

(72) Inventors: Hongtao Liu, Wuhan (CN); Xiangnan Zhao, Wuhan (CN); Yuanyuan Min, Wuhan (CN)

(21) Appl. No.: 18/676,271

(22) Filed: May 28, 2024

(30) Foreign Application Priority Data
Feb. 23, 2024 (CN) 202410205117.7

(51) Int. Cl. G11C 16/10; G11C 16/08; G11C 16/26

(52) U.S. Cl. CPC G11C 16/102; G11C 16/08; G11C 16/26

(57) ABSTRACT

According to one aspect of the present disclosure, memory devices are provided. An example memory device may include a peripheral circuit coupled to word lines, each of which may be coupled to a corresponding memory cell in each memory string. The peripheral circuit may be configured to receive a set of write data including N pages of data. The peripheral circuit may be configured to execute a first program operation to write m pages of data included in the set of write data to memory cells of the memory strings coupled to a first word line. The peripheral circuit may be configured to execute a second program operation to write at least p pages of data included in the set of write data to memory cells of the memory strings coupled to a second word line. A sum of m and p may equal N.

### CROSS-REFERENCE TO RELATED APPLICATIONS

This application claims the benefit of priority to Chinese Application No. 202410205117.7, filed on Feb. 23, 2024, the content of which is incorporated herein by reference in its entirety.

### TECHNICAL FIELD

Examples of the present disclosure relate to the technical field of semiconductors, and in examples to memory devices, memory systems, and operation methods.

### BACKGROUND

A memory device is a memory apparatus configured to store information in modern information technology. As a typical non-volatile semiconductor memory, the Not-And (NAND) type memory gradually becomes a mainstream product in the storage market as it has a relatively high storage density, controllable production costs, appropriate programming and erasing speeds, and a retention characteristic.

### SUMMARY

According to one aspect of the present disclosure, a memory device is provided. The memory device may include a block including a plurality of memory strings. Each memory string may include a plurality of memory cells. The memory device may include a plurality of word lines. Each word line may be coupled to a corresponding memory cell in each memory string. The memory device may include a peripheral circuit coupled to the plurality of word lines. The peripheral circuit may be configured to receive a first set of write data including N pages of data. The peripheral circuit may be configured to execute a first program operation to write m pages of data included in the first set of write data to memory cells of the memory strings coupled to a first word line. The peripheral circuit may be configured to execute a second program operation to write at least p pages of data included in the first set of write data to memory cells of the memory strings coupled to a second word line. A sum of m and p may equal N.

In some implementations, the first word line may be adjacent to the second word line, and the second word line may not be the first one among word lines to be programed in the block. In some implementations, the peripheral circuit may be further configured to acquire m pages of data included in a second set of write data. In some implementations, the second set of write data may include N pages of data, and the m pages of data included in the second set of write data are written, before the second program operation is executed, to the memory cells of the memory strings coupled to the second word line. In some implementations, the peripheral circuit may be further configured to execute the second program operation to write the m pages of data included in the second set of write data and the p pages of data included in the first set of write data to the memory cells of the memory strings coupled to the second word line.

In some implementations, the first word line may be adjacent to the second word line, and the second word line may be the first one among word lines to be programed in the block. In some implementations, the peripheral circuit may be further configured to execute the second program operation to only write the p pages of data included in the first set of write data to the memory cells of the memory strings coupled to the second word line.

In some implementations, the first word line is adjacent to the second word line, and the first word line is not the last one among word lines to be programed in the block. In some implementations, the peripheral circuit may be further configured to receive a third set of write data comprising N pages of data. In some implementations, the peripheral circuit may be further configured to acquire the m pages of data included in the first set of write data. In some implementations, the peripheral circuit may be further configured to execute a third program operation to write p pages of data included in the third set of write data and the m pages of data included in the first set of write data to the memory cells of the memory strings coupled to the first word line.

In some implementations, the first word line may be adjacent to the second word line, and the first word line may be the last one among word lines to be programed in the block. In some implementations, the peripheral circuit may be further configured to only write the m pages of data included in the first set of write data to the memory cells of the memory strings coupled to the first word line.

In some implementations, the peripheral circuit may include a first latch configured to temporarily store the m pages of data included in the second set of write data. In some implementations, the first latch may be one of a plurality of data latches that temporarily store the N pages of data of the first set of write data.

In some implementations, the peripheral circuit may further include a second latch configured to temporarily store the m pages of data included in the second set of write data. In some implementations, the second latch may not be one of a plurality of data latches that temporarily store the N pages of data of the first set of write data.

In some implementations, one memory cell coupled to the second word line may store N-bit data after programming is completed.

In some implementations, one memory cell coupled to the second word line may store p-bit data after programming is completed.

In some implementations, one memory cell coupled to the first word line may store N-bit data after programming is completed.

In some implementations, one memory cell coupled to the first word line may store m-bit data after programming is completed.

In some implementations, the first set of write data and the second set of write data may both include 3 pages of data. In some implementations, m may be 1, and p may be 2. In some implementations, after programming of the memory cells of the memory strings coupled to the second word line is completed, distribution of threshold voltages of the memory cells may be in a trinary-level cell (TLC) mode.

In some implementations, the first set of write data and the second set of write data may both include 3 pages of data. In some implementations, m may be 1, and p may be 2. In some implementations, after programming of the memory cells of the memory strings coupled to the second word line is completed, distribution of threshold voltages of the memory cells may be in a double-level cell DLC mode.

In some implementations, the first set of write data and the third set of write data may both include 3 pages of data. In some implementations, m may be 1, and p may be 2. In some implementations, after programming of the memory cells of the memory strings coupled to the first word line is completed, distribution of threshold voltages of the memory cells may be in a TLC mode.

In some implementations, the first set of write data may include 3 pages of data. In some implementations, m may be 1, and p may be 2. In some implementations, after programming of the memory cells of the memory strings coupled to the first word line is completed, distribution of threshold voltages of the memory cells may be in an SLC mode.

In some implementations, the peripheral circuit may be further configured to execute a read operation in response to a read command, so as to obtain first read data from the memory cells of the memory strings coupled to the first word line, and to obtain second read data from the memory cells of the memory strings coupled to the second word line. In some implementations, the first read data may include the m pages of data included in the first set of write data. In some implementations, the second read data may include the p pages of data included in the first set of write data.

According to another aspect of the present disclosure, a memory system is provided. The memory system may include a memory controller configured to send a first set of write data comprising N pages of data. The memory system may include a memory device coupled to the memory controller. The memory device may include a block including a plurality of memory strings. Each memory string may include a plurality of memory cells. The memory device may include a plurality of word lines. Each word line may be coupled to a corresponding memory cell in each memory string. The memory device may include a peripheral circuit coupled to the plurality of word lines. The peripheral circuit may be configured to receive the first set of write data including the N pages of data. The peripheral circuit may be configured to execute a first program operation to write m pages of data included in the first set of write data to memory cells of the memory strings coupled to a first word line. The peripheral circuit may be configured to execute a second program operation to write at least p pages of data included in the first set of write data to memory cells of the memory strings coupled to a second word line. A sum of m and p may equal N.

In some implementations, the first word line may be adjacent to the second word line, and the second word line may not be the first one among word lines to be programed in the block. In some implementations, the peripheral circuit may be further configured to acquire m pages of data included in a second set of write data. In some implementations, the second set of write data may include N pages of data, and the m pages of data included in the second set of write data are written, before the second program operation is executed, to the memory cells of the memory strings coupled to the second word line. In some implementations, the peripheral circuit may be further configured to execute the second program operation to write the m pages of data included in the second set of write data and the p pages of data included in the first set of write data to the memory cells of the memory strings coupled to the second word line.

In some implementations, the first word line may be adjacent to the second word line, and the second word line may be the first one among word lines to be programed in the block. In some implementations, the peripheral circuit may be further configured to execute the second program operation to only write the p pages of data included in the first set of write data to the memory cells of the memory strings coupled to the second word line.

In some implementations, the first word line may be adjacent to the second word line, and the first word line may not be the last one among word lines to be programed in the block. In some implementations, the memory controller may be further configured to send a third set of write data comprising N pages of data. In some implementations, the peripheral circuit may be further configured to receive the third set of write data. In some implementations, the peripheral circuit may be further configured to acquire the m pages of data included in the first set of write data. In some implementations, the peripheral circuit may be further configured to execute a third program operation to write p pages of data included in the third set of write data and the m pages of data included in the first set of write data to the memory cells of the memory strings coupled to the first word line.

In some implementations, the first word line may be adjacent to the second word line, and the first word line may be the last one among word lines to be programed in the block. In some implementations, the peripheral circuit may be further configured to only write the m pages of data included in the first set of write data to the memory cells of the memory strings coupled to the first word line.

In some implementations, the memory controller may be further configured to send a first read command and first physical address information to the memory device. In some implementations, the first physical address information includes a first address indicating the first word line and a second address indicating the second word line. In some implementations, the peripheral circuit may be further configured to, in response to the first read command, obtain, according to the first address, first read data from the memory cells of the memory strings coupled to the first word line. In some implementations, the peripheral circuit may be further configured to obtain, according to the second address, second read data from the memory cells of the memory strings coupled to the second word line. In some implementations, the peripheral circuit may be further configured to feed back the first read data and the second read data to the memory controller. In some implementations, the first read data may include the m pages of data included in the first set of write data, and the second read data may include the p pages of data included in the first set of write data.

In some implementations, the memory controller may be further configured to send a second read command and second physical address information to the memory device. In some implementations, the peripheral circuit may be further configured to, in response to the second read command, obtain, according to the second physical address information, a first address indicating the first word line and a second address indicating the second word line. In some implementations, the peripheral circuit may be further configured to obtain, according to the first address, first read data from the memory cells of the memory strings coupled to the first word line. In some implementations, the peripheral circuit may be further configured to obtain, according to the second address, second read data from the memory cells of the memory strings coupled to the second word line. In some implementations, the peripheral circuit may be further configured to feed back the first read data and the second read data to the memory controller. In some implementations, the first read data may include the m pages of data included in the first set of write data, and the second read data may include the p pages of data included in the first set of write data.

According to a further aspect of the present disclosure, a method of a memory device is provided. The method may include receiving a first set of write data comprising N pages of data. The method may include executing a first program operation to write m pages of data included in the first set of write data to memory cells of memory strings coupled to a first word line. The method may include executing a second program operation to write at least p pages of data included in the first set of write data to memory cells of the memory strings coupled to a second word line. A sum of m and p may equal N. The memory device may include a block comprising a plurality of memory strings. Each memory string may include a plurality of memory cells, and a plurality of word lines. Each word line may be coupled to a corresponding memory cell in each memory string.

In some implementations, the first word line may be adjacent to the second word line, and the second word line may not be the first one among word lines to be programed in the block. In some implementations, the method may further include acquiring m pages of data included in a second set of write data. In some implementations, the second set of write data may include N pages of data. In some implementations, the m pages of data included in the second set of write data are written, before the second program operation is executed, to the memory cells of the memory strings coupled to the second word line. In some implementations, the method may further include executing the second program operation to write the m pages of data included in the second set of write data and the p pages of data included in the first set of write data to the memory cells of the memory strings coupled to the second word line.

In some implementations, the first word line may be adjacent to the second word line, and the second word line may be the first one among word lines to be programed in the block. In some implementations, the method may further include executing the second program operation, to only write the p pages of data included in the first set of write data to the memory cells of the memory strings coupled to the second word line.

In some implementations, the first word line may be adjacent to the second word line, and the first word line may not be the last one among word lines to be programed in the block. In some implementations, the method may further include receiving a third set of write data comprising N pages of data. In some implementations, the method may further include acquiring the m pages of data included in the first set of write data. In some implementations, the method may further include executing a third program operation to write p pages of data included in the third set of write data and the m pages of data included in the first set of write data to the memory cells of the memory strings coupled to the first word line.

In some implementations, the first word line may be adjacent to the second word line, and the first word line may be the last one among word lines to be programed in the block. In some implementations, the method may further include only writing the m pages of data included in the first set of write data to the memory cells of the memory strings coupled to the first word line.

In some implementations, the method may further include executing a read operation in response to a read command, so as to obtain first read data from the memory cells of the memory strings coupled to the first word line, and to obtain second read data from the memory cells of the memory strings coupled to the second word line. In some implementations, the first read data may include the m pages of data included in the first set of write data. In some implementations, the second read data may include the p pages of data included in the first set of write data.

### BRIEF DESCRIPTION OF THE DRAWINGS

In the drawings not necessarily drawn to scale, the like numerals may describe similar components in different views. Like numerals having different letter suffixes may represent different examples of similar components. The drawings illustrate generally, by way of example, but not by way of limitation, various examples discussed in the present document.

FIG. 1 is a schematic structural diagram of a memory device provided by examples of the present disclosure;

FIG. 2 is a schematic structural diagram of a memory cell array provided by examples of the present disclosure;

FIG. 3 is a schematic diagram of an example memory device comprising a peripheral circuit provided by an example of the present disclosure;

FIG. 4 is a schematic diagram of a plurality of sub-blocks comprised in a block provided by an example of the present disclosure;

FIG. 5 is a schematic cross-sectional view of an example memory array comprising a NAND memory string provided by an example of the present disclosure;

FIG. 6 is a schematic structural diagram of a peripheral circuit of a memory device provided by an example of the present disclosure;

FIG. 7 is a schematic diagram of distribution of threshold voltages being in a TLC mode after the programming of memory cells coupled to a word line is completed provided by an example of the present disclosure;

FIG. 8 is a schematic diagram of a program flow of a word line WLn+1 and a word line WLn in a block provided by an example of the present disclosure;

FIG. 9 is a schematic diagram of a program flow of memory cells coupled to an inner word line provided by an example of the present disclosure;

FIG. 10 is a schematic diagram of a mode presented by distribution of threshold voltages of memory cells comprised after the programming of each word line in a block is completed provided by an example of the present disclosure;

FIG. 11 is a schematic diagram of distribution of threshold voltages of memory cells coupled to an inner word line provided by an example of the present disclosure;

FIG. 12 is a schematic structural diagram of a memory system provided by an example of the present disclosure;

FIG. 13 is a block diagram of an example system having a memory system provided by an example of the present disclosure;

FIG. 14 is a schematic diagram of an example memory card having a memory system provided by an example of the present disclosure;

FIG. 15 is a schematic diagram of an example solid-state drive having a memory system provided by an example of the present disclosure;

FIG. 16 is a schematic structural diagram of a memory controller provided by an example of the present disclosure; and

FIG. 17 is a flow diagram of an operation method of a memory device provided by an example of the present disclosure.

### DETAILED DESCRIPTION

Example implementations disclosed by the present disclosure will be described below in more detail with reference to the drawings. Although example implementations of the present disclosure are shown in the figures, it is to be understood that, the present disclosure may be implemented by any form without being limited by the implementations as set forth herein. On the contrary, these implementations are provided for more thorough understanding of the disclosure, and to fully convey a scope disclosed in the present disclosure to a person skilled in the art.

In the following descriptions, a lot of details are given in order to provide the more thorough understanding of the present disclosure. However, it is apparent to a person skilled in the art that the present disclosure may be implemented without one or more of these details. In other examples, in order to avoid confusion with the present disclosure, some technical features well-known in the field are not described. Namely, all the features of the actual examples are not described here, and well-known functions and structures are not described in detail.

In the drawings, the sizes of a layer, a region, and an element and their relative sizes may be exaggerated for clarity. The same reference sign represents the same element throughout.

It should be understood that while the element or the layer is referred to as being “on”, “adjacent to”, “connected to” or “coupled to” other elements or layers, it may be directly on the other elements or layers, adjacent to, connected or coupled to the other elements or layers, or an intermediate element or layer may be existent. In contrast, while the element is referred to as being “directly on”, “directly adjacent to”, “directly connected to” or “directly coupled to” other elements or layers, the intermediate element or layer is not existent. It should be understood that although terms first, second, third and the like may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teaching of the present disclosure, a first element, component, region, layer or section discussed below may be represented as a second element, component, region, layer or section. While the second element, component, region, layer or section is discussed, it does not mean that the first element, component, region, layer or section is necessarily existent in the present disclosure.

Spatial relation terms, such as “under”, “below”, “lower”, “underneath”, “above”, “upper” and the like, may be used here for conveniently describing so that a relationship between one element or feature shown in the drawings and other elements or features is described. It should be understood that in addition to orientations shown in the drawings, the spatial relationship terms are intended to further include the different orientations of a device in use and operation. For example, if the device in the drawings is turned over, then the elements or the features described as “below” or “underneath” or “under” other elements may be oriented “on” the other elements or features. Therefore, the exemplary terms “below” and “under” may include two orientations of up and down. The device may be otherwise oriented (rotated by 90 degrees or other orientations) and the spatial descriptions used here are interpreted accordingly.

A purpose of the terms used here is only to describe the examples and not as limitation to the present disclosure. While used here, singular forms of “a”, “an” and “said/the” are also intended to include plural forms, unless the context clearly indicates another mode. It should also be understood that terms “comprised of” and/or “including”, while used in the description, determine the existence of the described features, integers, steps, operations, elements and/or components, but do not exclude the existence or addition of one or more other features, integers, steps, operations, elements, components, and/or groups. As used herein, a term “and/or” includes any and all combinations of related items listed.

In order to understand the features and technical contents of the examples of the present disclosure in more detail, the implementation of the examples of the present disclosure are described in detail below with reference to the drawings, which are for reference only and are not intended to limit the examples of the present disclosure.

It should be understood that “one example” and “an example” mentioned throughout the specification mean that features, structures or characteristics related to the example is included in at least one example of the present disclosure. Therefore, “in one example” or “in an example” appearing throughout the specification does not always refer to the same example. In addition, these features, structures or characteristics may be combined in one or more examples in any proper manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent goodness and badness of the examples.

The methods disclosed in several method embodiments provided in this application can be combined arbitrarily without conflict to obtain new method embodiments.

Examples of the present disclosure relate to a memory device and an operation method. Interference between layers is reduced by writing a same set of received data to memory cells coupled to different word lines.

Examples of the present disclosure are further described in detail below with reference to the drawings and examples.

With the development of a memory technology, more and more layers of 3D NAND are stacked in order to increase storage density. In this case, due to the limitation of deep-hole etching technology, stacking more layers on a channel (CH) at a same depth will inevitably shrink the thicknesses of each gate conductive layer (Lg) and each dielectric layer (Ls), such that, when such a memory device is programmed, coupling interference between word lines is caused and becomes increasingly severe, thereby reducing a margin of a read window, and hence, the reliability of the memory device.

Examples of the present disclosure provide a memory device. When the memory device is programmed, a set of data to be written is separately written to memory cells coupled to two word lines, and if a word line of the two word lines is previously written with data, the data is read out first and written to the word line together with data, which is to be written to the word line, in the set of data to be written, such that the coupling interference between the word lines is reduced.

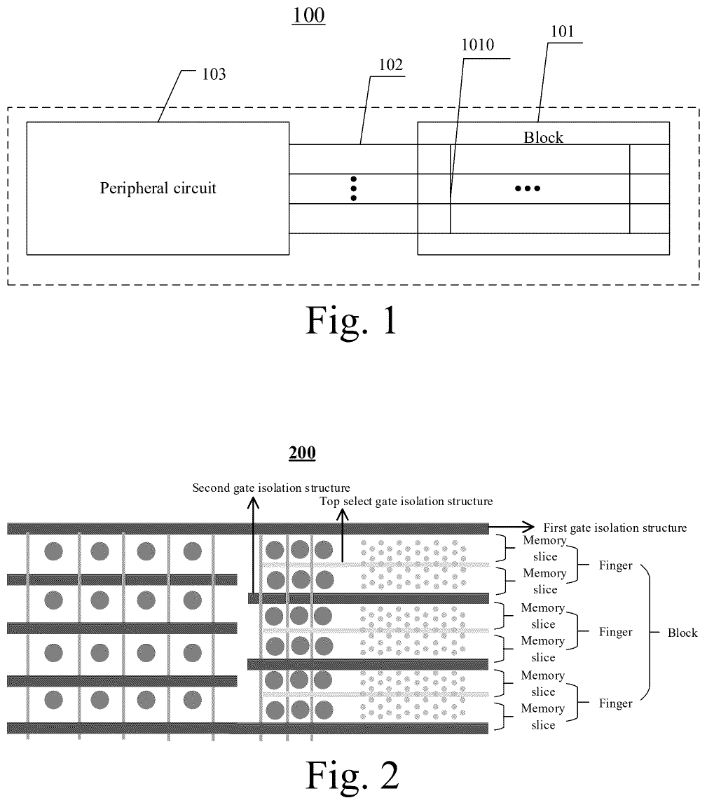

In an example, FIG. 1 shows a schematic structural diagram of a memory device provided by an example of the present disclosure. The memory device 100 may include, e.g., a block 101 including a plurality of memory strings 1010. Each memory string may include a plurality of memory cells and a plurality of word lines 102. Each word line may be coupled to a corresponding memory cell in each memory string 1010. A peripheral circuit 103 coupled to the plurality of word lines. The peripheral circuit 103 may be configured to receive a first set of write data, where the first set of write data may include N pages of data. The peripheral circuit 103 may be configured to execute a first program operation to write m pages of data included in the first set of write data to memory cells of the memory strings coupled to a first word line. The peripheral circuit 103 may be configured to execute a second program operation to write at least p pages of data included in the first set of write data to memory cells of the memory strings coupled to a second word line. A sum of m and p may equal N.

It is to be noted that, the memory device 100 may refer to a device for storing programs and/or data, and may include the block 101, the peripheral circuit 103, and the plurality of word lines 102 for connecting the peripheral circuit 103 and the block 101. In an actual application process, the memory device may include the plurality of blocks, and these blocks may constitute a memory cell array. The memory cell array may be a storage medium for storing the programs and/or data; and the peripheral circuit 103 may be a general term for various circuits configured to control the memory cell array and then store the programs and/or data to the memory cell array.

FIG. 2 shows a schematic structural diagram of a memory cell array 200 of a three-dimensional NAND memory device. As shown in FIG. 2, the memory cell array of the three-dimensional NAND memory device is formed by a plurality of memory cell rows that are staggered in parallel and are parallel to a gate isolation structure. Every two memory cell rows are spaced apart by the gate isolation structure and a top select gate isolation structure. Each memory cell row may include the plurality of memory cells. The gate isolation structure may include a first gate isolation structure and a second gate isolation structure. The first gate isolation structure divides the memory cell array into a plurality of blocks. A plurality of second gate isolation structures may divide a block into a plurality of fingers. The top select gate isolation structure disposed in the middle of each finger may divide the finger into two portions, so as to divide the finger into two memory slices. One block shown in FIG. 2 includes 6 memory slices. In a practical application, the number of memory slices in one block is not limited thereto.

In some examples, each block may be coupled to a plurality of word lines, and a plurality of memory cells coupled to each individually-controlled word line form a memory page. The memory page mentioned here may be a physical page. In an example, all memory cells coupled to one word line in each memory slice in FIG. 2 constitute one memory page.

It is to be noted that the row number of memory cell rows between the gate isolation structure and the top select gate isolation structure in FIG. 2 is only an example, but is not used to limit the number of memory cell rows comprised in one finger of the three-dimensional NAND memory in the present disclosure. During a practical application, the number of memory cell rows comprised in one finger may be adjusted according to actual situations, and is, for example, 2, 4, 8, 16, etc.

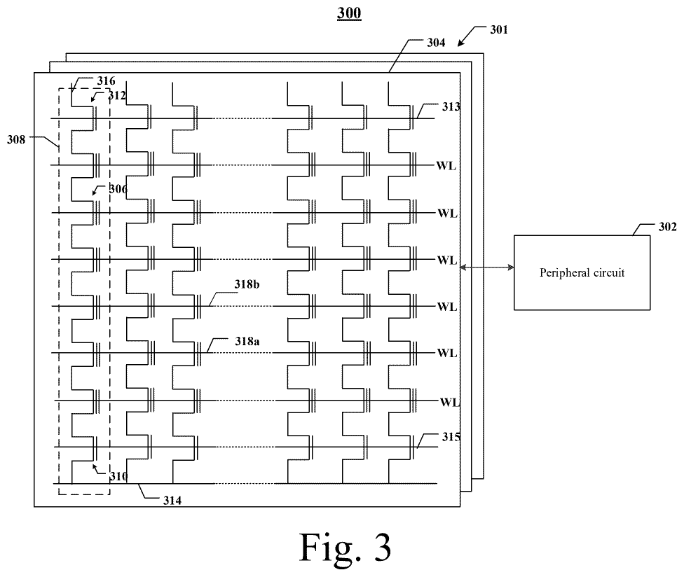

FIG. 3 shows a schematic structural diagram of a memory device 300 including a peripheral circuit and a memory cell array. As shown in FIG. 3, the memory device 300 may be a NAND flash memory device, is an example of the memory device 100 in FIG. 1, and includes a memory cell array 301 and a peripheral circuit 302, where memory cells 306 of the memory cell array 301 are provided in a form an array of NAND memory strings 308, and each NAND memory string 308 extends perpendicularly above a substrate (not shown). In some examples, each NAND memory string 308 includes the plurality of memory cells 306 coupled in series and stacked perpendicularly. Each memory cell 306 may maintain a continuous analog value, such as a voltage or a charge, which depends on the number of electrons trapped within a memory area of the memory cell 306. Each memory cell 306 may be either a floating-gate type memory cell that includes a floating-gate transistor, or a charge-trapping type memory cell that includes a charge-trapping transistor. An example of the memory string 1010 described above is the memory string 308.

In some examples, each memory cell 306 is an SLC that has two possible data states and thus may store one bit of data. For example, a first data state “0” may correspond to a first voltage range, and a second data state “1” may correspond to a second voltage range. In some examples, the first voltage range and the second voltage range may be called as the distribution of threshold voltages of the memory cells. In some examples, each memory cell 306 may be a multi-level cell (MLC). For example, the MLC may store two bits per cell (which may also be referred to as a double-level cell (DLC)), may store three bits per cell (which may also be referred to as a trinary-level cell (TLC)), may store four bits per cell (which may also be referred to as a quadruple level cell (QLC)), etc. The data states of the memory cells, regardless of types, all include one erased state and (one or more) programmed states. When a program operation is executed on the memory cell, the memory cell in the erased state is programmed to one programmed state. Generally, a voltage value within the voltage range corresponding to the programmed state of the memory cell is relatively large.

As shown in FIG. 3, each NAND memory string 308 may include a source select gate (SSG) 310 at a source terminal of the memory string and a drain select gate (DSG) 312 at a drain terminal of the memory string. The SSG 310 and the DSG 312 may be configured to activate a selected NAND memory string 308 (a column of the array) during read and program (or write) operations. In some examples, sources of the NAND memory strings 308 in a same block 304 are coupled through a same source line (SL) 314 (for example, a common SL). In other words, according to some implementations, all the NAND memory strings 308 in the same block 304 have an array common source (ACS). According to some implementations, the DSG 312 of each NAND memory string 308 is coupled to a respective bit line 316, and data may be read and written from the bit line 316 via an output bus (not shown). In some examples, each NAND memory string 308 is configured to be selected or unselected by applying a select voltage (e.g., above a threshold voltage of a transistor having the DSG 312) or an unselect voltage (e.g., 0 V) to the respective DSG 312 via one or more drain selective lines or top selective lines 313 and/or by applying a select voltage (e.g., above a threshold voltage of a transistor having the SSG 310) or an unselect voltage (e.g., 0 V) to the respective SSG 310 via one or more source selective lines or bottom selective lines 315.

As shown in FIG. 3, the NAND memory strings 308 may be organized into a plurality of blocks 304, and each of the plurality of blocks 304 may have a common source line 314 (e.g., coupled to the ground). In some examples, each block 304 is a basic data unit for an erase operation, e.g., all of the memory cells 306 on the same block 304 are erased at the same time. In order to erase the memory cells 306 in a selected block 304, the source lines 314 coupled to the selected block 304 as well as unselected blocks 304 that are in a same plane as the selected block 304 may be biased with an erase voltage (Vers) such as a high positive voltage 20 V or higher. It is to be understood that, in some examples, the erase operation may be executed at a half block level, a quarter block level, or a level having any suitable number of blocks or any suitable fractions of a block. As shown in FIG. 3, the memory cells 306 of the adjacent NAND memory string 308 may be coupled through word lines 318, that is to say, the same word line 318 may be coupled to the memory cells (e.g., corresponding memory cells) at a same position in the plurality of memory strings.

In some examples, one block 304 may be logically divided into a plurality of sub-blocks, where one sub-block may be referred to as a sub block, and the plurality of memory cells coupled on one word line in one sub-block may be used as a program unit (which may also be referred to as a (logical) page, and the page may refer to a logical page). Data written to one page may occupy one or more physical pages. It is to be understood that, the concept of the page here is a logical one, and a correspondence relationship between the page and a physical memory cell may be determined according to the control of a memory cell array of a memory controller, and is no longer described in detail herein.

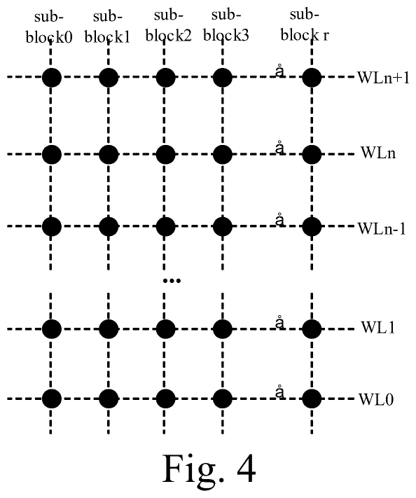

In an example, as shown in FIG. 4, one block may include r+1 sub-blocks such as sub-block0, sub-block1, sub-block2, sub-block3, . . . , sub-block r, etc.

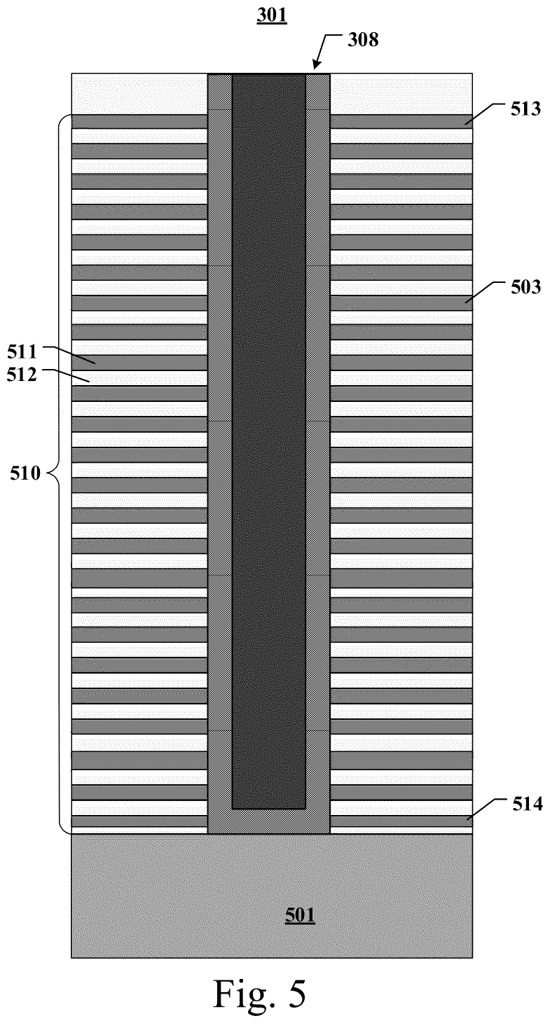

FIG. 5 shows a cross-sectional view of an example memory cell array 301 including a NAND memory string 308, according to some aspects of the present disclosure. As shown in FIG. 5, the NAND memory string 308 may include a stack structure 510. The stack structure 510 includes a plurality of gate layers 511 and a plurality of insulation layers 512, which are sequentially and alternately stacked, and a memory string 308 vertically running through the gate layers 511 and the insulation layers 512. The gate layers 511 and the insulation layers 512 may be alternately stacked, and two adjacent gate layers 511 are spaced apart by one insulation layer 512. The number of pairs of the gate layers 511 and the insulation layers 512 in the stack structure 510 may determine the number of memory cells included in the memory cell array 301.

A constituent material of the gate layers 511 may include a conductive material. The conductive material includes, but is not limited to, tungsten (W), cobalt (Co), copper (Cu), aluminum (Al), polysilicon, doped silicon, silicides, or any combination thereof. In some implementations, each gate layer 511 includes a metal layer, e.g., a tungsten layer. In some implementations, each gate layer 511 includes a doped polysilicon layer. Each gate layer 511 may include a control gate around the memory cells. The gate layer 511 at the top of the stack structure 510 may laterally extend as a top select gate line 513, e.g. a TSG line 313, where the top select gate line 513 is a lead-out line of the top select gate (TSG) 312 described above, so as to introduce a respective select voltage or unselect voltage. The gate layer 511 at the bottom of the stack structure 510 may laterally extend as a bottom select gate line 514, e.g. a source selective line or a bottom selective line 315, where the bottom select gate line 514 is a lead-out line of the bottom select gate (BSG) 310 described above, so as to introduce a respective select voltage or unselect voltage. The gate layers 511 laterally extending between the top select gate line and the bottom select gate line may be used as word line layers 503, and these word line layers 503 are the word lines 318 described above.

In some examples, the stack structure 510 may be disposed on a substrate 501. The substrate 501 may include silicon (e.g., single crystalline silicon), silicon germanium (SiGe), gallium arsenide (GaAs), germanium (Ge), silicon on insulator (SOI), germanium on insulator (GOI), or any other suitable materials.

In some examples, the NAND memory string 308 includes a channel structure that extends through the stack structure 510 vertically. In some implementations, the channel structure includes a channel hole filled with (one or more) semiconductor materials (e.g., as a semiconductor channel) and (one or more) dielectric materials (e.g., as a memory film). In some implementations, the semiconductor channel includes silicon, e.g., polysilicon. In some implementations, the memory film is a composite dielectric layer including a tunneling layer, a storage layer (also known as a “charge trap/storage layer”), and a blocking layer. The channel structure may have a cylindrical shape (e.g., a pillar shape). According to some implementations, the semiconductor channel, the tunneling layer, the storage layer, and the blocking layer are arranged radially from the center toward the outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In an example, the memory film may include a composite layer of silicon oxide/silicon oxynitride/silicon oxide (ONO).

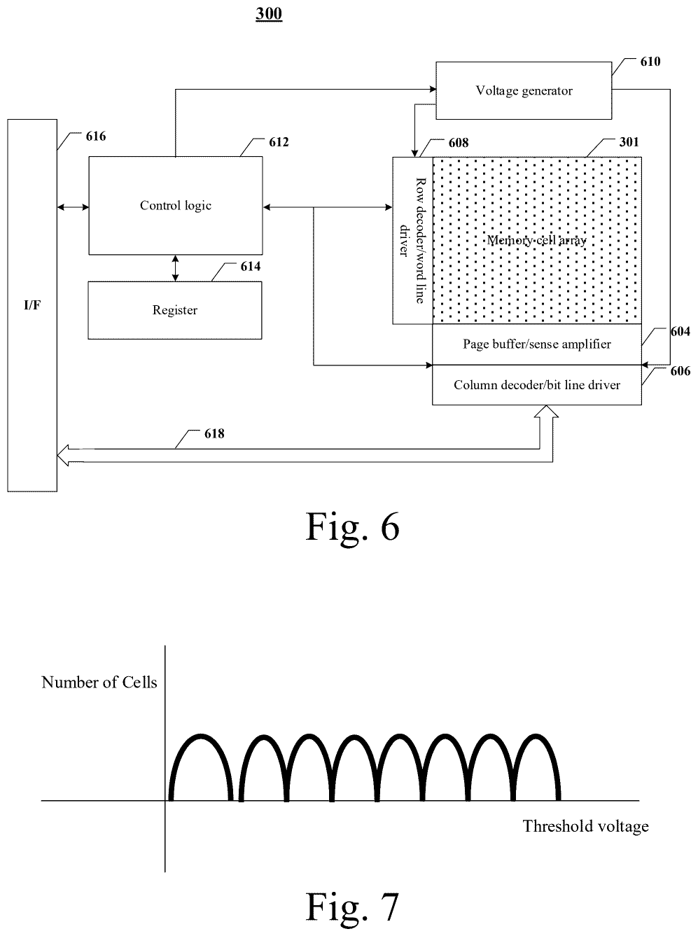

Referring back to FIG. 3, the peripheral circuit 302 may be coupled to the memory cell array 301 through the bit lines 316, the word lines 318, the source lines 314, the SSG lines 315, and the DSG lines 313. The peripheral circuit 302 may include any suitable analog, digital, and hybrid signal circuits for promoting operations of the memory cell array 301 by applying and sensing voltage signals and/or current signals to and from each target memory cell 306 via the bit lines 316, the word lines 318, the source lines 314, the SSG lines 315, and the DSG lines 313. The peripheral circuit 302 may include various types of peripheral circuits formed using a metal-oxide-semiconductor (MOS) technology. For example, FIG. 6 shows some example peripheral circuits. The peripheral circuit 302 includes a page buffer/sense amplifier 604, a column decoder/bit line driver 606, a row decoder/word line driver 608, a voltage generator 610, a control logic 612, a register 614, an interface 616, and a data bus 618. It is to be understood that, in some examples, additional circuits not shown in FIG. 6 may also be included as well.

In an example, the page buffer/sense amplifier 604 may be configured to read and program (write) data from and to the memory cell array 301 according to a control signal from the control logic 612. In one example, the page buffer/sense amplifier 604 may store program data (or referred to as write data) to be programmed to the memory cell, which is coupled to one word line, in the memory cell array 301. In another example, the page buffer/sense amplifier 604 may execute a program verification operation to ensure that the data has been properly programmed into the memory cell 306 coupled to the selected word line 318. In yet another example, the page buffer/sense amplifier 604 may also sense a low power signal from the bit line 316 that represents a data bit stored in the memory cell 306, and amplifies a small voltage swing to a recognizable logic level in the read operation. The column decoder/bit line driver 606 may be configured to be controlled by the control logic 612, and select one or more NAND memory strings 308 by applying a bit line voltage generated from the voltage generator 610.

The row decoder/word line driver 608 may be configured to be controlled by the control logic 612, select/unselect the blocks 304 of the memory cell array 301, and select/unselect the word lines 318 of the blocks 304. The row decoder/word line driver 608 may further be configured to drive the word lines 318 using a word line voltage generated from the voltage generator 610. In some implementations, the row decoder/word line driver 608 may also select/unselect and drive the SSG line 315 and the DSG line 313. As described below in detail, the row decoder/word line driver 608 is configured to execute an erase operation on the memory cells 306 coupled to (one or more) selected word lines 318. The voltage generator 610 may be configured to be controlled by the control logic 612, and generate the word line voltage (such as, a read voltage, a program voltage, a pass voltage, a local voltage, a verify voltage, etc.), the bit line voltage, and a source line voltage, which are to be supplied to the memory cell array 301.

The control logic 612 may be coupled to each circuit described above and configured to control operations of each peripheral circuit. The register 614 may be coupled to the control logic 612 and include a state register, a command register, and an address register, so as to store state information, command operation codes (OP code), and command addresses for controlling the operations of each peripheral circuit. The interface 616 may be coupled to the control logic 612, and act as a control buffer to buffer and relay control commands received from a host (not shown) to the control logic 612 and state information received from the control logic 612 to the host. The interface 616 may also be coupled to the column decoder/bit line driver 606 via the data bus 618 and act as a data I/O interface and a data buffer to buffer and relay the data to and from the memory cell array 301.

It is to be noted that block 304 described above may be an example of one of the blocks. The plurality of word lines 318 described above may be an example of one of the plurality of word lines. The NAND memory string described above may be an example of one of the memory strings. That is to say, the concept of the blocks, sub-blocks, word lines, and memory strings in the memory device 100, and a connection and position relationship among them may all refer to the descriptions from FIGS. 1 to 6. On the basis of the descriptions in FIGS. 1 to 6 for the memory device provided by examples of the present disclosure, when the memory cells are programmed, the peripheral circuit is configured to: receive a first set of write data (data to be written) including N pages of data, execute a first program operation to write m pages of data included in the first set of write data to memory cells of the memory strings coupled to a first word line, and execute a second program operation to write the remaining p pages of data in the first set of write data to memory cells of the memory strings coupled to a second word line. That is to say, the first set of write data is divided into the m pages of data and the p pages of data, and the m pages of data and the p pages of data are respectively written to the memory cells of the memory strings coupled to the first word line and the memory cells coupled to the second word line. In some examples, the memory cells included in the memory string coupled to the first word line may constitute one sub-block, e.g., one sub-block such as shown in FIG. 4, sub-block0, sub-block1, sub-block3, etc. Likewise, the memory cells included in the memory string coupled to the second word line may constitute one sub-block.

Herein, the N pages of data may refer to data in N pages, where N is a positive integer. The first word line and the second word line may be two adjacent word lines among the plurality of word lines, where the so-called adjacent word lines may be a word line 318a and a word line 318b in the NAND memory string 308 such as shown in FIG. 3. Furthermore, in the first word line and the second word line, the programming of the memory cells of the memory strings coupled to the first word line is completed later than that of the memory cells of the memory strings coupled to the second word line. In other words, the programming of the memory cells coupled to the first word line starts later than that of the memory cells coupled to the second word line, and the memory cells of the memory strings coupled to the first word line is completed later than that of the memory cells coupled to the second word line. The completion of programming may mean that the memory cells are programmed to a target data state. The target data state may be a programmed state corresponding to one of the SLC, the DLC, the TLC, and the QLC described above.

In an example, if a program sequence is positive, e.g., the programming starts in sequence from the memory cells coupled to the word lines close to the source line 314 towards the memory cells coupled to the word lines close to the bit line 316 are. In this case, the first word line may be the word line 318b, and the second word line may be the word line 318a. That is, the programming of the memory cells coupled to the first word line is later than that of the memory cells coupled to the second word line. If a program sequence is negative, e.g., the programming starts in sequence from the memory cells coupled to the word lines close to the bit line 316 towards the memory cells coupled to the word lines close to the source line 314. In this case, the first word line may be the word line 318a, and the second word line may be the word line 318b. That is, the programming of the memory cells coupled to the first word line is later than that of the memory cells coupled to the second word line.

In the memory device provided by the examples of the present disclosure, the received first set of write data including N pages of data is divided into two sets of data, one set of data is written to the memory cells coupled to the first word line, and the other set of data is written to the memory cells coupled to the second word line, where at least P pages of data in the first set of write data are written to the memory cells coupled to the second word line, such that multi-bit storage of the memory cells may be completed, and program interference between the word lines is significantly reduced.

In some examples, the first word line is adjacent to the second word line, and the second word line is not the first one among word lines to be programed in the block. The peripheral circuit is further configured to: acquire m pages of data included in a second set of write data, where the second set of write data includes N pages of data, and the m pages of data included in the second set of write data are written, before the second program operation is executed, to the memory cells of the memory strings coupled to the second word line; and execute the second program operation to write the m pages of data included in the second set of write data and the p pages of data included in the first set of write data to the memory cells of the memory strings coupled to the second word line.

When the data is written to the memory cells included in the block, the memory cells may be programmed in a positive or negative sequence, the programming in the positive or negative sequence has been described in detail above, and thus not described herein again in order to save space. In regardless of the program sequence, there will be a sequence for programming multiple word lines; for example, the word line (e.g., the word line close to a bottom select line) at the bottom of the programming in the positive sequence is the first one among word lines to be programmed; and for another example, the word line (e.g., the word line close to a top select line) at the top of the programming in the negative sequence is the first one among word lines to be programmed.

Herein, if the second word line is not the first one among word lines to be programmed, the peripheral circuit is further configured to acquire m pages of data included in the second set of write data. The second set of write data also includes N pages of data, and the m pages of data included in the second set of write data have been written, before the second program operation is executed, to the memory cells of the memory strings coupled to the second word line. In this case, the m pages of data of the second set of write data that are written to the memory cells of the memory cell string coupled to the second word line need to be read out first. The reading the m pages of data of the second set of write data described here may refer to only reading the m pages of data of the second set of write data from the memory cell array, and temporarily store same to the page buffer/sense amplifier 604, without feeding back to the memory controller side. Then, the second program operation is executed. In this case, the executed second program operation needs to write the m pages of data included in the second set of write data and the p pages of data included in the first set of write data together to the memory cells of the memory strings coupled to the second word line. That is to say, when the second word line is an inner word line to be programmed, the N pages of data will still be written to the memory cells coupled to the second word line, but the N pages of data include the p pages of data of the first set of write data that are written during current programming, as well as the m pages of data of the second set of write data that are written during previous programming. In this way, data writing to the memory cells coupled to the second word line is completed in two times, such that coupling interference between the word lines is reduced.

In some examples, the peripheral circuit includes a first latch. The first latch is further configured to temporarily store the m pages of data included in the second set of write data, where the first latch is one of the plurality of data latches that temporarily store the N pages of data of the first set of write data.

Herein, the first latch may refer to one of the plurality of data latches included in the page buffer/sense amplifier 604. That is to say, the plurality of data latches included in the page buffer/sense amplifier 604 may store the N pages of data of the first set of write data, and one of the data latches may be configured to temporarily store the m pages of data included in the second set of write data.

From the above descriptions, it can be learned that the m pages of data included in the second set of write data are previously written to the memory cells coupled to the second word line. Before the second program operation is executed, the m pages of data included in the second set of write data need to be read from the memory cells coupled to the second word line, and then the m pages of data included in the second set of write data and the p pages of data included in the first set of write data are together written to the memory cells coupled to the second word line. Then, the read m pages of data included in the second set of write data need to be temporarily stored for subsequent use when the second program operation is executed.

Herein, the read m pages of data included in the second set of write data may be first temporarily stored in one of the plurality of data latches. During an actual operation, if the first latch is one of the plurality of latches storing the N pages of data, and in this case, if one of the data latches is required to temporarily store the m pages of data included in the second set of write data, free data latches are required, and the m pages of data included in the second set of write data need to be written, together with the p pages of data included in the first set of write data, to the memory cells coupled to the second word line. In this case, the above-mentioned first program operation of writing the p pages of data included in the first set of write data to the memory cells of the memory strings coupled to the first word line needs to be performed before the operation of reading the m pages of data included in the second set of write data, so as to free up the data latches storing the p pages of data included in the first set of write data, for use of reading. In this case, in chronological order, the first program operation is executed first, and then a read operation is executed, and the second program operation is performed last.

In some other examples, the peripheral circuit further includes a second latch configured to temporarily store the m pages of data included in the second set of write data. The second latch is not one of the plurality of data latches that temporarily store the N pages of data of the first set of write data.

Herein, the second latch may be another latch or data latch in the page buffer/sense amplifier 604. That is to say, if there is still another latch or data latch that is free in the page buffer/sense amplifier 604, the read m pages of data included in the second set of write data may be first temporarily stored in the free latch. In this case, an execution sequence of the first program operation and the second program operation is not specifically defined. That is, the first program operation may precede the second program operation, or the second program operation precedes the first program operation, but the programming of the memory cells of the memory strings coupled to the first word line is completed prior to that of the memory cells coupled to the second word line (e.g., the memory cells of the memory strings coupled to the first word line being first programmed to the target data state).

In some examples, one memory cell coupled to the second word line stores N-bit data after programming is completed.

In one example, the first set of write data and the second set of write data both include 3 pages of data, where m is 1, and p is 2. After the programming of the memory cells of the memory strings coupled to the second word line is completed, distribution of threshold voltages of the memory cells is in a TLC mode.

In some examples, the first word line is adjacent to the second word line, and the second word line is the first one among word lines to be programed in the block. The peripheral circuit is further configured to execute the second program operation to only write the p pages of data included in the first set of write data to the memory cells of the memory strings coupled to the second word line.

It is to be noted that the second word line introduced above is not the first one among word lines to be programmed. It is introduced here that, when the second word line is the first one among word lines to be programmed, in this case, since the first set of write data is the first received write data, no data is stored in the memory cells coupled to the second word line, such that the read operation is naturally not required, and only the p pages of data in the first set of write data are written.

In this case, one memory cell coupled to the second word line stores p-bit data after programming is completed.

In one example, the first set of write data and the third set of write data both include 3 pages of data, where m is 1, and p is 2. After the programming of the memory cells of the memory strings coupled to the first word line is completed, distribution of threshold voltages of the memory cells is in a TLC mode.

The above describes the programming of the memory cells coupled to the second word line, and the situation in which the programming of the memory cells of the memory strings coupled to the first word line is completed and some program operations are described below.

In some examples, the first word line is adjacent to the second word line, and the first word line is not the last one among word lines to be programed in the block. The peripheral circuit may further be configured to: receive a third set of write data including N pages of data; acquire the m pages of data included in the first set of write data; and execute a third program operation to write p pages of data included in the third set of write data and the m pages of data included in the first set of write data to the memory cells of the memory strings coupled to the first word line.

It is to be noted that, if the first word line is not the last one among word lines to be programmed, the first word line is also an inner word line to be programmed. In this case, the first program operation executed by the memory cells of the memory strings coupled to the first word line is not an operation of completion of the final programming of the memory cells of the memory strings coupled to the first word line, it is needed to further execute a third program operation, so as to write the received p pages of data in the third set of write data to the memory cells of the memory strings coupled to the first word line together with the m pages of data included in the first set of write data that are previously written in the first program operation. Before the third program operation is executed, the m pages of data included in the first set of write data are read and temporarily stored in the first latch or the second latch. Detail descriptions may be referred to descriptions of the above-mentioned second program operation of the memory cells coupled to the second word line, and are not described herein again.

In this case, one memory cell coupled to the first word line stores N-bit data after programming is completed.

In one example, the first set of write data and the third set of write data both include 3 pages of data, where m is 1, and p is 2. After the programming of the memory cells of the memory strings coupled to the first word line is completed, distribution of threshold voltages of the memory cells is in a TLC mode.

In some other examples, if the first word line is adjacent to the second word line, and the first word line is the last one among word lines to be programed in the block, the peripheral circuit is further configured to only write the m pages of data included in the first set of write data to the memory cells of the memory strings coupled to the first word line.

That is, when the first word line is the last one among word lines to be programmed, the write data is no long received later, and in this case, only the m pages of data included in the first set of write data are written to the memory cells of the memory strings coupled to the first word line.

In this case, one memory cell coupled to the first word line stores m-bit data after programming is completed.

In one example, the first set of write data includes 3 pages of data, where m is 1, and p is 2. After the programming of the memory cells of the memory strings coupled to the first word line is completed, distribution of threshold voltages of the memory cells is in an SLC mode.

The above describes some operations during the programming of the block, and reading after programming is performed according to the above aspects is introduced below.

In some examples, the peripheral circuit is further configured to: execute a read operation in response to a read command, so as to obtain first read data from the memory cells of the memory strings coupled to the first word line, and to obtain second read data from the memory cells of the memory strings coupled to the second word line. Here, the first read data includes the m pages of data included in the first set of write data, and the second read data includes the p pages of data included in the first set of write data.

It is to be noted that, from the perspective of a client, the client still wants to read data required, such that, regardless of the memory device or the memory controller performing certain processing, finally the first read data is obtained from the memory cells of the memory strings coupled to the first word line, and the second read data is obtained from the memory cells of the memory strings coupled to the second word line; and the first read data includes the m pages of data included in the first set of write data, and the second read data includes the p pages of data included in the first set of write data. That is, what is read is the first set of write data, the second set of write data, or the third set of write data, etc., originally received.

An example is provided below, so as to describe the technical solutions of the present disclosure.

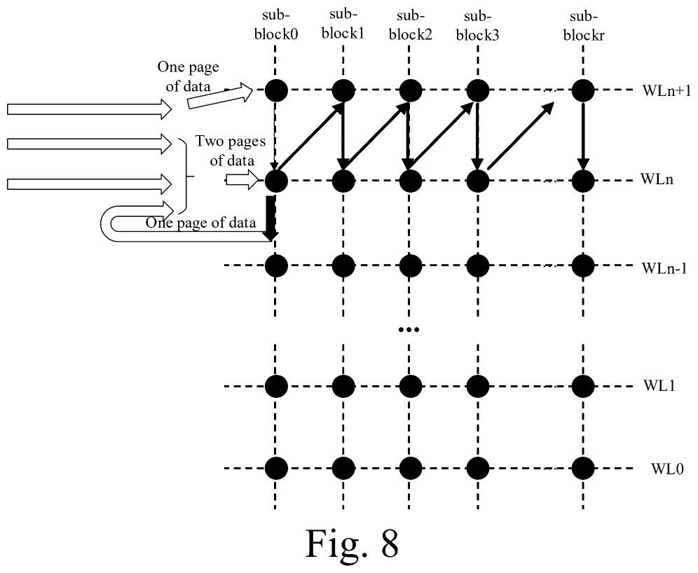

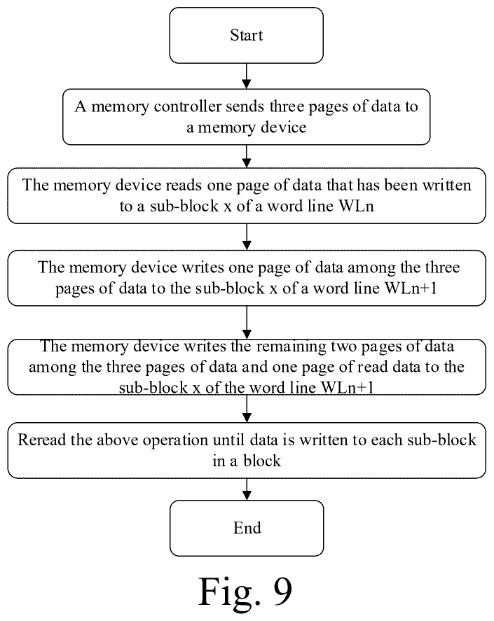

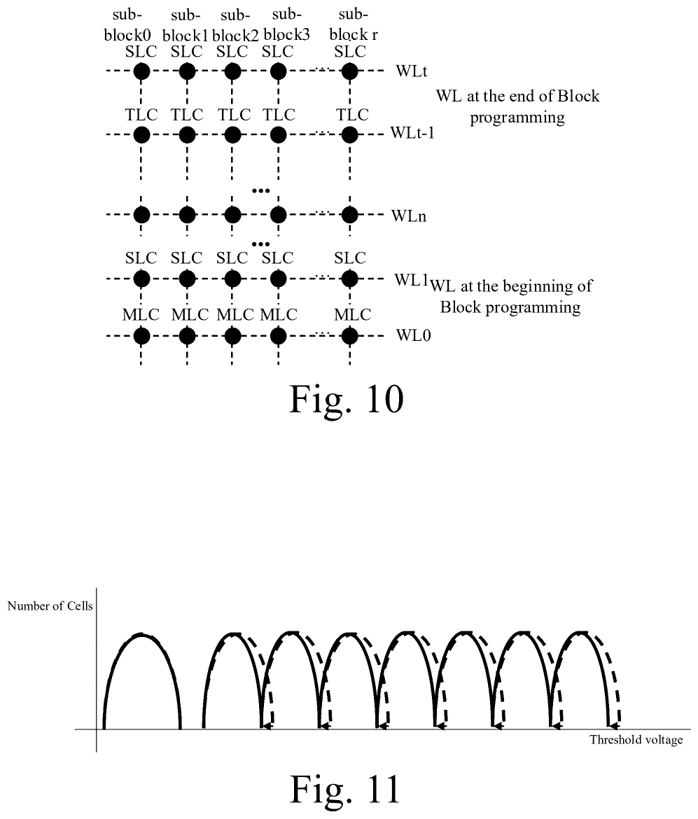

FIG. 7 shows a schematic diagram of distribution of threshold voltages being in a TLC mode after the programming of memory cells coupled to a word line is completed provided by an example of the present disclosure. FIG. 8 shows a schematic diagram of a program flow of a word line WLn+1 and a word line WLn in a block provided by an example of the present disclosure. FIG. 9 shows a schematic diagram of a program flow of memory cells coupled to an inner word line. FIG. 10 shows a schematic diagram of a mode presented by distribution of threshold voltages of memory cells included after the programming of each word line in a block is completed provided by an example of the present disclosure. FIG. 11 shows a schematic diagram of distribution of threshold voltages of memory cells coupled to an inner word line provided by an example of the present disclosure. FIGS. 7-11 will be described together.

In an example, in FIG. 7, an ordinate may refer to the number of memory cells (e.g., the number of cells); and an abscissa may be a threshold voltage.

In FIG. 8, a block includes a plurality of sub-blocks, which respectively are sub-block0, sub-block1, sub-block2, sub-block3, . . . , sub-block r, . . . . Furthermore, the block is coupled to a plurality of word lines, and the plurality of word lines respectively are WL0, WL1, . . . , WLn−1, WLn, WLn+1, . . . . Furthermore, N being 3, m being 1, P being 2, and a program sequence being positive (e.g., programming starting from the word line WL0) are used as an example for description.

In the memory device and at the program sequence, the programming of the memory cells coupled to each word line of the block may be classified into three cases.

In the first case, two word lines to be programmed do not include an edge word line (e.g., the first one among word lines to be programmed and the last one among word lines to be programmed), e.g., the two word lines to be programmed are inner word lines, not the first word line WL0 to be programmed, and not the last one among word lines to be programmed (not shown here). Under such conditions, during programming, the programming of the memory cells coupled to the word line WLn and the word line WLn+1 in the sub-block0 is used as an example. In an example, during programming, on a memory controller side, three pages of data (e.g., the first set of write data, respectively being page1, page2, and page3) are still transmitted for one time without changing a data transmission mode of the memory controller. On a memory device side, the data of the page1, page2, and page3 is received and buffered, then one page of data (m pages of data of the first set of write data) among the three pages of data is first written to the memory cells in the sub-block0 coupled to the word line WLn+1 (e.g., the first word line), and the remaining two pages of data (p pages of data of the first set of write data) among the three pages of data are written to the memory cells in the sub-block0 coupled to the word line WLn (e.g., the second word line). The page of data that is written to the memory cells in the sub-block coupled to the word line WLn+1 may be any one page of data in the three pages of data, and may be the first-buffered page data, such as page1, and the exact page of data can be set according to actual situations. The memory cells coupled to the word line WLn is written with the remaining two pages of data (p pages of data of the first set of write data, such as page2 and page3 of the first set of write data) among the three pages of data, and one page of data (e.g., the m pages of data of the second set of write data, such as page1 of the second set of write data) among the three pages of data that is received when the word line WLn and the word line WLn−1 are previously programmed. Then, among the received three pages of data (third set of write data), one page of data (m pages of data in the third set of write data) among the three pages of data is written to the memory cells in the sub-block0 coupled to the word line after the word line WLn+1; and one page of data (the m pages of the first set of write data) among the previously-received three pages of data, as well as the remaining two pages of data (p pages of the third set of write data) among the three pages received currently, are written to the memory cells in the sub-block0 coupled to the word line WLn+1. Finally, when the programming of the memory cells coupled to the word line WLn is completed, the distribution of the threshold voltages is in a TLC mode; and when the programming of the memory cells coupled to the word line WLn+1 is completed, the distribution of the threshold voltages is in the TLC mode.

In an example, as shown in FIG. 9, the programming of a selected sub-block coupled to an inner word line may include the following flows: the memory controller sends 3 pages of data to the memory device; the memory device reads one page of data that has been written to the memory cells in the selected sub-block (e.g., sub-block x) coupled to the word line WLn; the memory device writes one page of data among the received 3 pages of data to the memory cells in the selected sub-block (e.g., sub-block x) coupled to the word line WLn+1; the memory device writes the remaining two pages of data among the received 3 pages of data and one page of read data to the memory cells in the selected sub-block (e.g., sub-block x) coupled to the word line WLn; the above operation is repeated until the programming of all sub-blocks coupled to the word line WLn is completed; and the programming of all sub-blocks coupled to each word line is completed according to the above approaches, so as to complete the programming of the entire block.

Herein, in the flows shown in FIG. 9, an extra latch is required to store one page of read data. That is to say, in a page buffer, in addition to data latches temporarily storing the received three pages of data to be written, one extra latch is required for temporarily storing the page of read data. According to the above descriptions, an actual implementation process may be implemented, through some logic control design, by first writing one page of data among the received 3 pages of data to the memory cells in the selected sub-block (e.g., sub-block x) coupled to the word line WLn+1, so as to free the data latch buffering the page of data, and then reading the page of data that has been written to the memory cells in the selected sub-block (e.g., sub-block x) coupled to the word line WLn, and temporarily storing same in the data latch.

It is to be noted that, when the block shown in FIG. 8 is programmed according to a program mode provided by an example of the present disclosure, the plurality of sub-blocks on a same word line are programmed in sequence, and then the plurality of sub-blocks on a next word line are programmed. That is to say, the block shown in FIG. 8 includes r+1 sub-blocks such as sub-block0, sub-block1, sub-block2, . . . , sub-block r, etc., and each word line is coupled to the memory cells in the r+1 sub-blocks at a same position. When the block with such structure is programmed, three pages of data that are received at one time are written to the memory cells coupled to two adjacent word lines (e.g., the word line WLn and the word line WLn+1) in a selected sub-block (e.g., sub-block0); and then three pages of data that are received next are written to the memory cells coupled to two adjacent word lines (e.g., the word line WLn and the word line WLn+1) in a next selected (e.g., sub-block1), and so on, until the programming of all the sub-blocks coupled to the word line WLn is completed. Then, the sub-blocks coupled to the word line WLn+1 and the word line WLn+2 are programmed in the manner described above, until the programming of the entire block is completed.

In the second case, the two word lines to be programmed include the first one among word lines to be programmed (edge word line). For example, when two word lines that include the word line WL0 and the word line WL1 are programmed, the word line WL0 is the first one among word lines to be programmed. In this case, no data is written to the memory cells coupled to the word line WL0 previously. Then, two pages of data among the received three pages of data are written to the memory cells coupled to the word line WL0, and the distribution of the threshold voltages of the memory cells is in a DLC mode. The word line WL1 is programmed according to the program mode in the first case, and finally, the distribution of the threshold voltages of the memory cells is in the TLC mode.

In the third case, the two word lines to be programmed include the last one among word lines to be programmed (edge word line). In this case, only one page of data among the received three pages of data is written to the memory cells coupled to the last one among word lines to be programmed, and the distribution of the threshold voltages of the memory cells is in an SLC mode. The memory cells coupled to the last one among word lines to be programmed are programmed according to the program mode in the first case, and finally, the distribution of the threshold voltages of the memory cells is in the TLC mode.

After each word line in the block is programmed according to the above three cases, and after the programming of the memory cells coupled to each word line in the block is completed, the modes presented by the distribution of the threshold voltages are shown in FIG. 10. The distribution of the threshold voltages of the memory cells coupled to inner word lines is in the TLC mode; the distribution of the threshold voltages of the memory cells coupled to the first one among word lines to be programmed is in the DLC mode; and the distribution of the threshold voltages of the memory cells coupled to the last one among word lines to be programmed is in the SLC mode.

After the programming is performed according to the program mode provided in the examples of the present disclosure, the distribution of the threshold voltages of the memory cells is more compact, a margin of a read window is large, and details are shown in FIG. 11. An ordinate may refer to the number of memory cells (e.g., the number of cells); and an abscissa may be a threshold voltage.

The memory device provided in the examples of the present disclosure realizes two-stage programming (such as two-stage programming in which the distribution of the threshold voltages is in the SLC mode to the TLC mode) by itself without changing a data transmission mode of the memory controller, such that coupling interference between the word lines is significantly reduced.

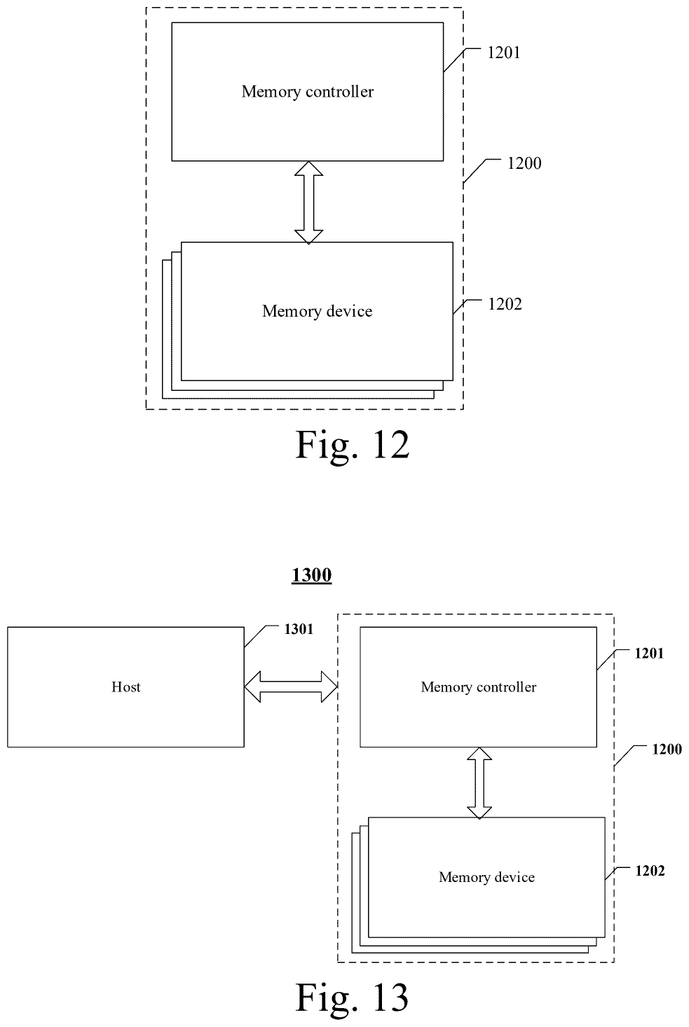

As shown in FIG. 12, an example of the present disclosure further provides a memory system 1200, which may include: a memory controller 1201 configured to send a first set of write data, where the first set of write data includes N pages of data; and a memory device 1202 coupled to the memory controller 1201 and including: a block including a plurality of memory strings, where each memory string includes a plurality of memory cells; a plurality of word lines, where each word line is coupled to a corresponding memory cell in each memory string; and a peripheral circuit coupled to the plurality of word lines and configured to: receive a first set of write data, where the first set of write data includes N pages of data; execute a first program operation to write m pages of data included in the first set of write data to memory cells of the memory strings coupled to a first word line; and execute a second program operation to write at least p pages of data included in the first set of write data to memory cells of the memory strings coupled to a second word line, where a sum of m and p equals N.

It is to be noted that the memory system may communicate with a host. The host and/or the memory system 1200 may be included in various products, for example, Internet-of-Things (IoT) devices such as refrigerators or other apparatuses, sensors, motors, mobile communication devices, automobiles, drones, and the like, so as to support processing, communication, or control of the products. In some examples, FIG. 13 shows a block diagram of an example system having a memory system provided by an example of the present disclosure. In FIG. 13, the system 1300 may include a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatus having a memory. As shown in FIG. 13, the system 1300 may include a host 1301 and a memory system 1200, where the memory system 1200 has one or more memory devices 1202 and a memory controller 1201; and the host 1301 may be a processor of an electronic apparatus, such as a central processing unit (CPU) or a system-on-chip (SOC), where the system on chip may be, for example, an application processor (AP). The host 1301 may be configured to send or receive data to or from the memory device 1202. In an example, the memory device 1202 may be any memory disclosed in the present disclosure. For example, the memory device may be a phase change random access memory (PCRAM), a three-dimensional flash, etc.

According to some implementations, the memory controller 1201 is coupled to the memory device 1202 and the host 1301. The memory controller 1201 is configured to control the memory device 1202. The memory controller 1201 may manage data stored in the memory device 1202, and communicate with the host 1301. In some examples, the memory controller 1201 is designed for operating in a low duty-cycle environment, such as secure digital (SD) cards, compact flash (CF) cards, universal serial bus (USB) flash drives, or other media for use in electronic apparatuses in a low duty-cycle environment, such as personal computers, digital cameras, mobile phones, etc. In some examples, the memory controller 1201 is designed for operating in a high duty-cycle environment such as solid state drives (SSDs) or embedded multi-media cards (eMMCs), where the SSDs or the eMMCs are used as data memories for mobile apparatuses in a high duty-cycle environment, such as smartphones, tablet computers, laptop computers, etc., and enterprise memory arrays. The memory controller 1201 may further be configured to control operations of the memory device 1202, e.g., such as read, erase, and program operations. The memory controller 1201 may further be configured to manage various functions with respect to data stored or to be stored in the memory device 1202, including, but not limited to, bad-block management, garbage collection, logical-to-physical address conversion, wear leveling, etc. In some implementations, the memory controller 1201 is further configured to process error correction codes (ECC) with respect to the data read from or written to the memory device 1202. The memory controller 1201 may further perform any other suitable functions as well, for example, formatting the memory device 1202. The memory controller 1201 may communicate with an external apparatus (e.g., the host 1301) according to a communication protocol. For example, the memory controller 1201 may communicate with the external apparatus through at least one of various interface protocols, such as a USB protocol, an MMC protocol, a peripheral component interconnection (PCI) protocol, a PCI-Express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

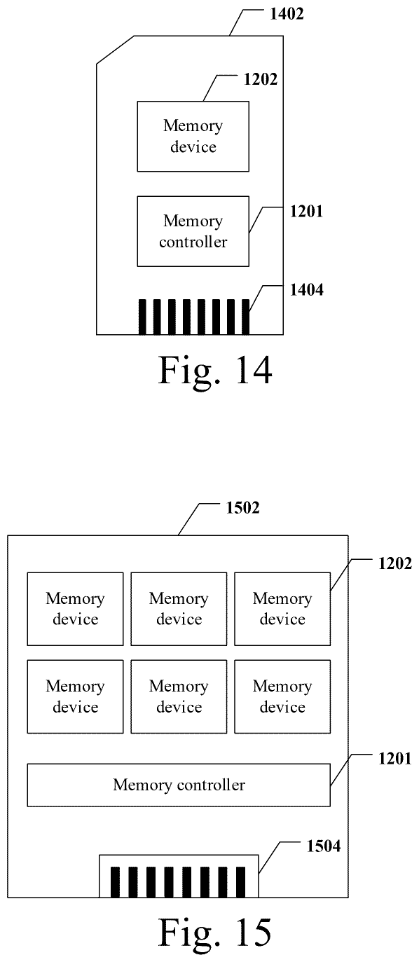

In some examples, the memory controller 1201 and the one or more memory devices 1202 may be integrated into various types of storage apparatuses, for example, be included in the same package (e.g., such as a universal flash storage (UFS) package or an eMMC package). That is to say, the memory system 1200 may be implemented and packaged into different types of end electronic products. In one example shown in FIG. 14, the memory controller 1201 and the single memory device 1202 may be integrated into a memory card 1402. The memory card may include a PC card (personal computer memory card international association (PCMCIA)), a CF card, a smart media (SM) card, a memory stick, a multimedia card (MMC, RS-MMC, MMCmicro), an SD card (SD, miniSD, microSD, SDHC), a UFS, etc. The memory card may further include a memory card connector 1404 coupling the memory card with a host (e.g., the host 1301 in FIG. 13). In another example shown in FIG. 15, the memory controller 1201 and a plurality of memory devices 1202 may be integrated into a solid-state drive (SSD) 1502. The SSD may further include an SSD connector 1504 coupling the SSD with a host (e.g., the host 1301 in FIG. 13). In some implementations, a storage capacity and/or operation speed of the SSD is greater than a storage capacity and/or operation speed of the memory card. Furthermore, the memory controller 1201 may further be configured to control erase, read, and write operations of the memory device 1202.

FIG. 16 shows a schematic diagram of an example structure of a memory controller provided by an example of the present disclosure. As shown in FIG. 16, the memory controller may include a front end interface 1601, a back end interface 1602, a processor 1603, and a memory 1604, where the above-mentioned components 1601, 1602, 1603, and 1604 in the memory controller 1201 may share a transmission signal in the memory controller 1201 through internal buses. In some examples, the front end interface 1601 may connect a host with an interface of the memory system 1200 in response to a protocol of the host coupled to the memory system 1200, and the front end interface 1601 exchanges a transmission command and a data operation between the host and the memory system 1200. The front end interface 1601 may process commands and data sent by the host, and may include at least one of the following: a universal serial bus (USB), a multi-media card (MMC), a peripheral component interconnection-express (PCI-e or PCIe), a small computer system interface (SCSI), a serial SCSI (SAS), a serial advanced technology attachment (SATA), a parallel advanced technology attachment (PATA), a small computer system interface (SCSI), an enhanced small disk interface (ESDI), and an integrated drive electronic (IDE). In some examples, the front end interface 1601 is a component of the memory system 1200 for exchanging data with the host, and may be implemented by firmware called a host interface layer (HIL).

The back end interface 1602 may be an interface for transmitting commands and data between the memory controller 1201 and the coupled memory device, and the memory controller 1201 is allowed to control the coupled memory device in response to a request transmitted from the host. The back end interface 1602 may generate a control signal for controlling the coupled memory device. In some examples, if the coupled memory device is a NAND flash memory, the back end interface 1602 may write or read data to or from the coupled memory device under the control of the processor 1603. The back end interface 1602 may process the commands and data between the memory controller 1201 and the coupled memory device, for example, operations of the interface of the NAND flash memory (e.g., such as operations between the memory controller 1201 and the coupled memory device). According to examples, through firmware called a flash interface layer (FIL), the back end interface 1602 may be implemented as the component for exchanging data with the coupled memory device.

The processor 1603 may be implemented as a microprocessor or a central processing unit (CPU). The memory system 1200 may include one or more processors 1603. The processor 1603 may control all operations of the memory system 1200. By way of example instead of limitation, the processor 1603 may control a program operation or a read operation of the coupled memory device in response to a write request or a read request from the host. According to examples, the processor 1603 may use or run the firmware to control all operations of the memory system 1200. In the present disclosure, the firmware may be referred to as a flash translation layer (FTL). The FTL may be used as an interface between the host and the coupled memory device to execute the operations. The host may transmit requests related to the write operation and the read operation to the coupled memory device through the FTL. For example, when the operation request by the host is executed in the coupled memory device, the memory controller 1201 uses the processor 1603. The processor 1603 coupled to the coupled memory device may process instructions or commands related to the commands from the host. The memory controller 1201 may execute e.g., a foregrounding operation of a command operation corresponding to the command inputted from the host, for example, a program operation corresponding to a write command, a read operation corresponding to a read command, an erase/discard operation corresponding to an erase/discard command, and a parameter setting operation corresponding to a setting parameter command having a setting command or a setting feature command.

For another example, the memory controller 1201 may execute a background operation on the coupled memory device through the processor 1603. By way of example instead of limitation, these background operations include a garbage collection (GC) operation, a wear leveling (WL) operation, and a bad block management operation to check or search for bad blocks. The garbage collection operation may include an operation of replicating and processing data stored in a block in the memory device to another block. The wear leveling operation may include an operation of exchanging and processing the stored data between the blocks of the memory device. The bad block management operation may include checking and processing bad blocks in the blocks of the coupled memory device.

The memory 1604 may be a work memory of the memory controller 1201, and is configured to store data for driving the memory controller 1201. In an example, when the memory controller 1201 controls the memory device in response to a request of the host, the memory 1604 may store firmware driven by the processor 1603 and data (such as metadata) required for driving the firmware.

The memory 1604 may also be a buffer memory of the memory controller 1201, and is configured to temporarily store write data transmitted from the host to the coupled memory device, and read data transmitted from the coupled memory device to the host. The memory 1604 may include a program memory, a data memory, a write buffer/cache, a read buffer/cache, a data buffer/cache, and a mapping buffer/cache, which are used for storing the write data and the read data. The memory 1604 may be implemented by utilizing a volatile memory. The memory 1604 may be implemented by utilizing a static random access memory (SRAM), a dynamic random access memory (DRAM), or both.

Although FIG. 16 shows that the memory 1604 is included in the memory controller 1201, the present disclosure is not limited thereto. In implementations, the memory 1604 may be included externally to the memory controller 1201, and the memory controller 1201 may input and output data to the memory 1604 through a separate memory interface (not shown). In some examples, a portion of space is divided in the memory of the host and provided to an SSD for use, and the memory controller of the SSD calls a portion of the memory of the host for use as its own memory through the front end interface, e.g. a host memory buffer (HMB) technology.

In an example of the present disclosure, the processor 1603 of the memory controller transmits N pages of data to the memory device through the back end interface 1602, controls the memory device to divide the N pages of data into two portions in response to the write command, and writes the same to two adjacent word lines. Moreover, the read command is sent subsequently, the data written to the memory device is read, and the read operation is described in detail subsequently, and thus is not described herein again.

The memory device 1202, which is the memory device shown in FIG. 1 or FIG. 3, is not described herein again.

Based on the memory system described above, in some examples, the first word line is adjacent to the second word line, and the second word line is not the first one among word lines to be programed in the block. The peripheral circuit may further be configured to: acquire m pages of data included in a second set of write data, where the second set of write data includes N pages of data, and the m pages of data included in the second set of write data are written, before the second program operation is executed, to the memory cells of the memory strings coupled to the second word line; and execute the second program operation to write the m pages of data included in the second set of write data and the p pages of data included in the first set of write data to the memory cells of the memory strings coupled to the second word line.

In some examples, the first word line is adjacent to the second word line, and the second word line is the first one among word lines to be programed in the block. The peripheral circuit is further configured to: execute the second program operation to only write the p pages of data included in the first set of write data to the memory cells of the memory strings coupled to the second word line.

In some examples, the first word line is adjacent to the second word line, and the first word line is not the last one among word lines to be programed in the block. The memory controller is further configured to send a third set of write data including N pages of data. The peripheral circuit is further configured to: receive the third set of write data; acquire the m pages of data included in the first set of write data; and execute a third program operation to write p pages of data included in the third set of write data and the m pages of data included in the first set of write data to the memory cells of the memory strings coupled to the first word line.

In some examples, the first word line is adjacent to the second word line, and the first word line is the last one among word lines to be programed in the block. The peripheral circuit is further configured to: only write the m pages of data included in the first set of write data to the memory cells of the memory strings coupled to the first word line.

It is to be noted that some operations of the memory device have been introduced in detail before in FIG. 7 to FIG. 11, may be understood here by referring to the above descriptions, and thus is not described herein again.

There are the following two methods for the memory controller to read data written to the memory device according to the above program methods.

In an example, in some examples, the memory controller may further be configured to send a first read command and first physical address information to the memory device, where the first physical address information includes a first address indicating the first word line and a second address indicating the second word line. The peripheral circuit is further configured to: in response to the first read command, obtain, according to the first address, first read data from the memory cells of the memory strings coupled to the first word line, and obtain, according to the second address, second read data from the memory cells of the memory strings coupled to the second word line; and feed back the first read data and the second read data to the memory controller, where the first read data includes the m pages of data included in the first set of write data; and the second read data includes the p pages of data included in the first set of write data.

It is to be noted that, when a read interaction between the host and the memory system is performed, a logic to physical (L2P) table needs to be used. The L2P table includes a plurality of L2P entries, and each L2P entry associates physical addresses of the memory cells included in the memory cell array in the memory device in the memory system with a logic address used by the host. When the read operation is performed, the host obtains a physical address of data to be read according to the L2P table and the provided logic address, and then the memory controller sends the read command and the physical address to the memory device, such that the memory device obtains the data from the physical address in response to the read command, so as to obtain read data.

In examples of the present disclosure, according to the indication of the host, the memory controller sends, to the memory device, the first read command, and the first physical address information including the first address indicating the first word line and the second address indicating the second word line; then the peripheral circuit, in response to the first read command, reads the first read data from the first address, reads the second read data from the second address, and feeds back the first read data and the second read data to the memory controller. That is to say, in this mode, the memory controller side obtains two physical addresses storing the data to be read, and feeds back the physical addresses to the memory device, such that the memory device directly respectively obtains the first read data and the second read data according to the two physical addresses, and feeds back the read data to the memory controller.

In implementations, if the above-mentioned read mode is to be employed, during programming, the memory device needs to feed back the physical addresses (the first addresses of the m pages of data of the first set of write data and the second addresses of the p pages of data of the first set of write data) of data storage to the memory controller; and the memory controller updates the L2P table, and the L2P table stores the logic addresses corresponding to the two physical addresses. In this way, during reading, the memory controller may directly send the physical addresses of data storage to the memory device.

In some examples, the memory controller may further be configured to send a second read command and second physical address information to the memory device. The peripheral circuit is further configured to: in response to the second read command, obtain, according to the second physical address information, a first address indicating the first word line and a second address indicating the second word line; obtain, according to the first address, first read data from the memory cells of the memory strings coupled to the first word line, and obtain, according to the second address, second read data from the memory cells of the memory strings coupled to the second word line; and feed back the first read data and the second read data to the memory controller, where the first read data includes the m pages of data included in the first set of write data; and the second read data includes the p pages of data included in the first set of write data.

In examples of the present disclosure, the memory controller sends the second read command and the second physical address; and then the peripheral circuit, in response to the second read command, obtains, according to the second physical address, the first address indicating the first word line and the second address indicating the second word line, then obtains the first read data according to the first address and obtains the second read data according to the second address. In this case, the memory controller does not obtain a real physical address of storage data, and the memory device obtains two physical addresses of real storage data according to the second physical address provided by the memory controller, so as to obtain the first read data and the second read data.

In implementations, if the above-mentioned read mode is to be employed, during programming, the L2P table obtained by the memory controller is well designed originally, and one logic address corresponds to one physical address. In this case, a correspondence relationship between the physical address in L2P and a real address (e.g., the first addresses of the m pages of data of the first set of write data and the second addresses of the p pages of data of the first set of write data) of data storage should be stored in the memory device, without feeding back the real physical address of data storage to the memory controller, and the L2P obtained by the memory controller is still well designed originally. In this way, during reading, the memory controller obtains the second physical address from the designed L2P according to the logic address provided by the host, and sends the second physical address to the memory device. The memory device obtains the first address indicating the first word line and the second address indicating the second word line according to the second physical address and the correspondence relationship stored during programming, so as to read the first read data and the second read data.

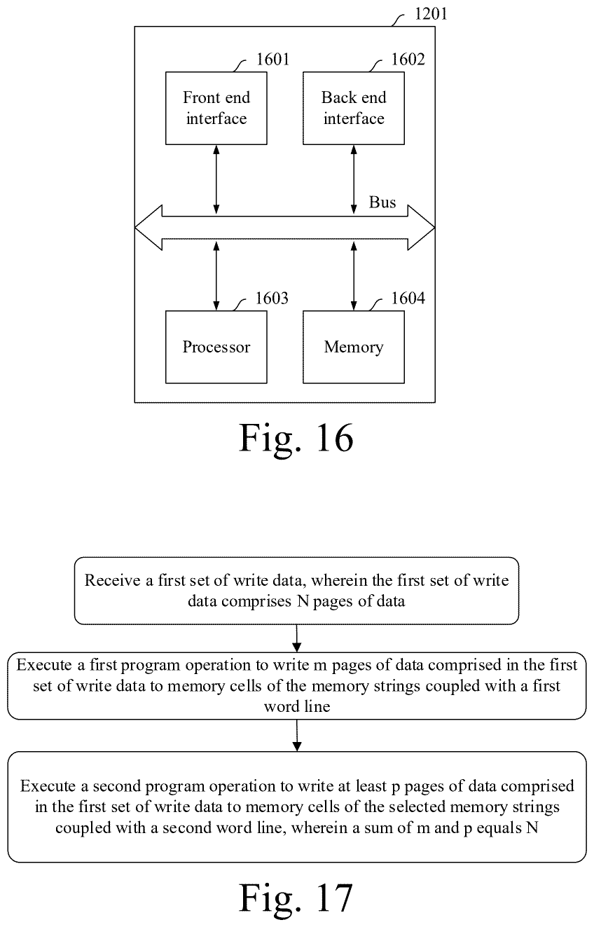

As shown in FIG. 17, yet another aspect of the examples of the present disclosure further provides an operation method of a memory device. The memory device includes: a block including a plurality of memory strings, where each memory string includes a plurality of memory cells; a plurality of word lines, where each word line is coupled to a corresponding memory cell in each memory string. The method may include: receiving a first set of write data, where the first set of write data includes N pages of data; executing a first program operation to write m pages of data included in the first set of write data to memory cells of the memory strings coupled to a first word line; and executing a second program operation to write at least p pages of data included in the first set of write data to memory cells of the memory strings coupled to a second word line, where a sum of m and p equals N.

In some examples, the first word line is adjacent to the second word line, and the second word line is the first one among word lines to be programed in the block. The operation method further includes executing the second program operation, and only writing the p pages of data included in the first set of write data to the memory cells of the memory strings coupled to the second word line.

In some examples, the first word line is adjacent to the second word line, and the first word line is not the last one among word lines to be programed in the block. The method further includes: receiving a third set of write data including N pages of data; acquiring the m pages of data included in the first set of write data; and executing a third program operation to write p pages of data included in the third set of write data and the m pages of data included in the first set of write data to the memory cells of the memory strings coupled to the first word line.

In some examples, the first word line is adjacent to the second word line, and the first word line is the last one among word lines to be programed in the block. The method further includes only writing the m pages of data included in the first set of write data to the memory cells of the memory strings coupled to the first word line.

In some examples, the operation method may further include: executing a read operation in response to a read command, so as to obtain first read data from the memory cells of the memory strings coupled to the first word line, and to obtain second read data from the memory cells of the memory strings coupled to the second word line, where the first read data includes the m pages of data included in the first set of write data; and the second read data includes the p pages of data included in the first set of write data.

It is to be noted that, the operation method of a memory device provided by the examples of the present disclosure is based on the operation method of a memory device provided by the previous examples. The way of operations has been described in detail before, and is not described herein again.

The above is only the implementations of the present disclosure and not intended to limit the scope of protection of the present disclosure. Any variations or replacements apparent to those skilled in the art within the technical scope disclosed by the present disclosure shall fall within the scope of protection of the present disclosure. Therefore, the protection scope of the present disclosure shall be subject to the protection scope of the claims.

What is claimed is:

1. A memory device, comprising:
a block comprising memory strings each comprising memory cells;
word lines each coupled to corresponding memory cell in each memory string; and
a peripheral circuit coupled to the word lines and configured to:
receive a first set of write data comprising N pages of data;
execute a first program operation to write m pages of data comprised in the first set of write data to memory cells of the memory strings coupled to a first word line; and
execute a second program operation to write at least p pages of data comprised in the first set of write data to memory cells of the memory strings coupled to a second word line, wherein a sum of m and p equals N.

2. The memory device of claim 1, wherein the first word line is adjacent to the second word line, and the second word line is not the first one among word lines to be programed in the block; and the peripheral circuit is further configured to:
acquire m pages of data comprised in a second set of write data, wherein the second set of write data comprises N pages of data, and the m pages of data comprised in the second set of write data are written, before the second program operation is executed, to the memory cells of the memory strings coupled to the second word line; and
execute the second program operation to write the m pages of data comprised in the second set of write data and the p pages of data comprised in the first set of write data to the memory cells of the memory strings coupled to the second word line.

3. The memory device of claim 1, wherein the first word line is adjacent to the second word line, and the second word line is the first one among word lines to be programed in the block; and the peripheral circuit is further configured to:
execute the second program operation to only write the p pages of data comprised in the first set of write data to the memory cells of the memory strings coupled to the second word line.

4. The memory device of claim 1, wherein the first word line is adjacent to the second word line, and the first word line is not the last one among word lines to be programed in the block; and the peripheral circuit is further configured to:
receive a third set of write data comprising N pages of data;
acquire the m pages of data comprised in the first set of write data; and
execute a third program operation to write p pages of data comprised in the third set of write data and the m pages of data comprised in the first set of write data to the memory cells of the memory strings coupled to the first word line.

5. The memory device of claim 1, wherein the first word line is adjacent to the second word line, and the first word line is the last one among word lines to be programed in the block; and the peripheral circuit is further configured to:
only write the m pages of data comprised in the first set of write data to the memory cells of the memory strings coupled to the first word line.

6. The memory device of claim 2, wherein the peripheral circuit comprises:
a first latch configured to temporarily store the m pages of data comprised in the second set of write data, wherein the first latch is one of data latches that temporarily store the N pages of data of the first set of write data.

7. The memory device of claim 2, wherein the peripheral circuit further comprises:
a second latch configured to temporarily store the m pages of data comprised in the second set of write data, wherein the second latch is not one of data latches that temporarily store the N pages of data of the first set of write data.

8. The memory device of claim 2, wherein one memory cell coupled to the second word line stores N-bit data after programming is completed.

9. The memory device of claim 3, wherein one memory cell coupled to the second word line stores p-bit data after programming is completed.

10. The memory device of claim 4, wherein one memory cell coupled to the first word line stores N-bit data after programming is completed.

11. The memory device of claim 5, wherein one memory cell coupled to the first word line stores m-bit data after programming is completed.

12. The memory device of claim 2, wherein the first set of write data and the second set of write data both comprise 3 pages of data, where m is 1, and p is 2; and
after programming of the memory cells of the memory strings coupled to the second word line is completed, distribution of threshold voltages of the memory cells is in a trinary-level cell (TLC) mode.

13. The memory device of claim 3, wherein the first set of write data and the second set of write data both comprise 3 pages of data, where m is 1, and p is 2; and
after programming of the memory cells of the memory strings coupled to the second word line is completed, distribution of threshold voltages of the memory cells is in a double-level cell DLC mode.

14. The memory device of claim 4, wherein the first set of write data and the third set of write data both comprise 3 pages of data, where m is 1, and p is 2; and
after programming of the memory cells of the memory strings coupled to the first word line is completed, distribution of threshold voltages of the memory cells is in a trinary-level cell (TLC) mode.

15. The memory device of claim 5, wherein the first set of write data comprises 3 pages of data, where m is 1, and p is 2; and
after programming of the memory cells of the memory strings coupled to the first word line is completed, distribution of threshold voltages of the memory cells is in a single-level cell (SLC) mode.

16. The memory device of claim 1, wherein the peripheral circuit is further configured to:
execute a read operation in response to a read command, so as to obtain first read data from the memory cells of the memory strings coupled to the first word line, and to obtain second read data from the memory cells of the memory strings coupled to the second word line; and
the first read data comprises the m pages of data comprised in the first set of write data; and
the second read data comprises the p pages of data comprised in the first set of write data.

17. A memory system, comprising:
a memory controller configured to send a first set of write data comprising N pages of data; and
a memory device coupled to the memory controller and comprising:
a block comprising memory strings, wherein each memory string comprises memory cells;
word lines, wherein each word line is coupled to a corresponding memory cell in each memory string; and
a peripheral circuit coupled to the word lines and configured to:
receive the first set of write data comprising the N pages of data;
execute a first program operation to write m pages of data comprised in the first set of write data to memory cells of the memory strings coupled to a first word line; and
execute a second program operation to write at least p pages of data comprised in the first set of write data to memory cells of the memory strings coupled to a second word line, wherein a sum of m and p equals N.

18. A method of operating a memory device, comprising:
receiving a first set of write data comprising N pages of data;
executing a first program operation to write m pages of data comprised in the first set of write data to memory cells of memory strings coupled to a first word line; and
executing a second program operation to write at least p pages of data comprised in the first set of write data to memory cells of the memory strings coupled to a second word line, wherein a sum of m and p equals N,
wherein the memory device comprises a block comprising memory strings, wherein each memory string comprises memory cells; and
word lines, wherein each word line is coupled to a corresponding memory cell in each memory string.

19. The method of claim 18, wherein the first word line is adjacent to the second word line, and the second word line is not the first one among word lines to be programed in the block; and the method further comprises:
acquiring m pages of data comprised in a second set of write data, wherein the second set of write data comprises N pages of data, and the m pages of data comprised in the second set of write data are written, before the second program operation is executed, to the memory cells of the memory strings coupled to the second word line; and
executing the second program operation to write the m pages of data comprised in the second set of write data and the p pages of data comprised in the first set of write data to the memory cells of the memory strings coupled to the second word line.

20. The method of claim 18, wherein the first word line is adjacent to the second word line, and the second word line is the first one among word lines to be programed in the block; and the method further comprises:
executing the second program operation, to only write the p pages of data comprised in the first set of write data to the memory cells of the memory strings coupled to the second word line.
